(19) United States
(12) Patent Application Publication
(10) Pub. No.: US 2024/0244387 A1
(43) Pub. Date: Jul. 18, 2024

(54) SYSTEMS, METHODS, AND DEVICES FOR AUDITORY ENHANCEMENT

(71) Applicant: Rockford Corporation, Tempe, AZ (US)

(72) Inventors: Wayne Connolly, Gilbert, AZ (US); Carl H. Lindquist, Phoenix, AZ (US); Jason Thomas, Mesa, AZ (US)

(21) Appl. No.: 18/410,506

(22) Filed: Jan. 11, 2024

Related U.S. Application Data
(60) Provisional application No. 63/479,643, filed on Jan. 12, 2023.

(51) Int. Cl. H04S 7/00; H04R 3/00

(52) U.S. Cl. CPC H04S 7/30; H04R 3/007; H04R 2205/026; H04R 2420/01; H04R 2430/01; H04S 2400/13

(57) ABSTRACT

Systems, methods, and devices are provided for a sub-frequency volume control unit for providing additional control of sub-frequency volume in a signal provided from a source unit to a subwoofer, without exceeding a maximum volume level of the subwoofer, the source unit having a master volume controller and a maximum volume level. The sub-frequency volume control unit may comprise: a sub-frequency volume control circuit for receiving the first audio signal and for generating a sub-amplifier signal; a variable volume control input device, wherein the sub-amplifier signal is amplified by an amount that is variably selected manually using the variable volume control input device, and wherein the sub-frequency volume control circuit is configured to amplify the first audio signal if, and only if, the master volume controller is providing the first audio signal at less than the maximum volume level; and an output for providing the sub-amplifier signal to a subwoofer.

### CROSS-REFERENCE TO RELATED APPLICATION

This application claims priority to, and the benefit of, U.S. Provisional Patent Application No. 63/479,643 filed on Jan. 12, 2023 entitled “Systems, Methods, and Devices for Auditory Enhancement”. The contents of the foregoing application are hereby incorporated by reference for all purposes (except for any subject matter disclaimers or disavowals, and except to the extent that the incorporated material is inconsistent with the express disclosure herein, in which case the language in this disclose controls).

### FIELD OF INVENTION

The present disclosure relates generally to a volume control circuit, and, in particular, to a multi-zone volume differentiating volume control circuit for use in a vehicle.

### BACKGROUND

Typically, systems for playing music have a source unit with a master volume control. For example, a source unit may provide a music signal to a subwoofer amplifier and to a 4 channel full-range audio amplifier. In this embodiment, the volume level of the music signal from the source unit is controlled by the master volume control of the source unit (e.g., a knob, dial, slider-bar, digital volume input, or the like). However, in certain applications, such as motorcycles, all-terrain vehicles, watercraft, and the like, external noises tend to vary, impacting the user's perception of the music being played. It is desirable to have more control over the user sound perception experience.

### SUMMARY

In an example embodiment, a volume control system, is disclosed, comprising: a source unit providing a first audio signal and a second audio signal, wherein the source unit has a master volume controller for providing the first audio signal and the second audio signal with a volume level between a 0% volume level and a 100% volume level; a volume control circuit configured to receive the first audio signal, to amplify the first audio signal, in accordance with user input to the volume control circuit for outputting a first amplified signal, if, and only if, the master volume controller is providing the first audio signal at less than the 100% volume level; a first speaker; and a second speaker, wherein the first amplified signal is provided to the first speaker, and wherein the second audio signal is provided to the second speaker.

In an example embodiment, a volume control unit is disclosed for providing additional control of volume in a first audio signal provided from a source unit to a first speaker, without exceeding a maximum volume level of the first speaker. In this example embodiment, the source unit has a master volume controller and a maximum volume level, the master volume controller controlling the volume of the first audio signal and a second audio signal. In this example embodiment, the volume control unit comprises: a circuit input for receiving a first audio signal from the source unit; a volume control circuit for receiving the first audio signal and for generating a first amplified signal for the first speaker; a variable volume control input device, wherein the first amplified signal is amplified by an amount that is variably selected manually using the variable volume control input device, and wherein the volume control circuit is configured to amplify the first audio signal if, and only if, the master volume controller is providing the first audio signal at less than the maximum volume level; and a circuit output for providing the first amplified signal to the first speaker.

In an example embodiment, a method of controlling an output volume level of a speaker, beyond volume control from a master volume controller of a first audio signal from a source unit, is disclosed. In this example embodiment, the master volume controller controls the volume level of the first audio signal and a second audio signal. The method comprises: receiving the first audio signal from the source unit at a volume control circuit, the first audio signal having a power level based on a master volume controller associated with the source unit; controlling a volume output by the speaker by generating a volume control output signal that is based on the source unit signal, wherein: the volume control output signal comprises the first audio signal without amplification, if the source unit is providing the first audio signal at the 100% volume level; and the volume control output signal comprises an amplified first audio signal in accordance with user input to the volume control circuit, wherein the amplified first audio signal is amplified sufficient to cause the volume output by the speaker to be between the master volume and 100% master volume when the master volume is less than 100%.

### BRIEF DESCRIPTION OF THE DRAWING FIGURES

Additional aspects of the present disclosure will become evident upon reviewing the non-limiting embodiments described in the specification and the claims taken in conjunction with the accompanying figures, wherein like numerals designate like elements, and:

FIG. 1 is a diagram illustrating an example volume control system:

FIG. 2 is a three-dimensional rendering illustrating a portion of the example volume control system:

FIG. 3 is a schematic diagram illustrating a portion of an example sub-frequency volume control circuit:

FIG. 4 is a flow diagram illustrating an example method:

FIG. 5 is a diagram illustrating another example volume control system; and

FIG. 6 is a diagram illustrating another example volume control system.

### DETAILED DESCRIPTION

Reference will now be made to the exemplary embodiments illustrated in the drawings, and specific language will be used herein to describe the same. It will nevertheless be understood that no limitation of the scope of the disclosure is thereby intended. Alterations and further modifications of the inventive features illustrated herein, and additional applications of the principles of the disclosure as illustrated herein, which would occur to one skilled in the relevant art and having possession of this disclosure, are to be considered within the scope of the disclosure.

In accordance with an example embodiment, systems, devices and methods are provided for added control in differentiating the volume between two audio signals from a single source unit/single master volume controller. In accordance with an example embodiment, systems, devices and methods are provided for added control of the perceived sub-frequency audio signal heard from a subwoofer or the like when the master volume is at less than maximum. This added control is very helpful in situations where environmental noise is variable and potentially quite loud.

In accordance with various example embodiments, a volume control circuit is installed between a source unit (e.g., radio, etc) and an amplifier associated with a first speaker, but is not installed between the source unit and a second speaker. The volume control unit is not a typical attenuation knob (volume up/down), but instead is configured to drive the amplifier to a variable but higher volume when the master (radio) volume is at a setting less than maximum. In this regard, the sub-frequency control knob is configured to “turn up” the amplifier to get more perceived output when listening to music at a master volume that is less than maximum, but never allow the sub-frequency amplifier to overdrive above the original maximum setting.

In accordance with one example embodiment, the volume control unit is a sub-frequency volume control unit installed between the source unit and a sub-frequency amplifier (e.g., subwoofer amplifier or “sub-amplifier”). In this example embodiment, the sub-frequency control knob is configured to “turn up” the sub-amplifier to get more perceived sub-frequency output when listening to music at a master volume that is less than maximum, but never allow the sub-frequency amplifier to overdrive above the original maximum setting.

For example, if the master volume is at a setting of 6 (out of 10) and if the sub-frequency control knob is set to max, the sub-amplifier may act as if it is at volume 8. It is noted that the full range audio amplifier is not adjusted, and so is still acting as it would with the master volume setting of 6. As the master volume is adjusted, the sub-frequency knob reacts accordingly, but will never “overdrive” the sub-amplifier. And again the full range audio amplifier will just adjust with the master volume alone. The sub-frequency knob (more generally a sub-frequency volume control unit) is therefore configured such that if both knobs (master volume and sub-frequency knob) are at maximum setting, the system acts as if the sub-frequency knob is not there (straight pass through).

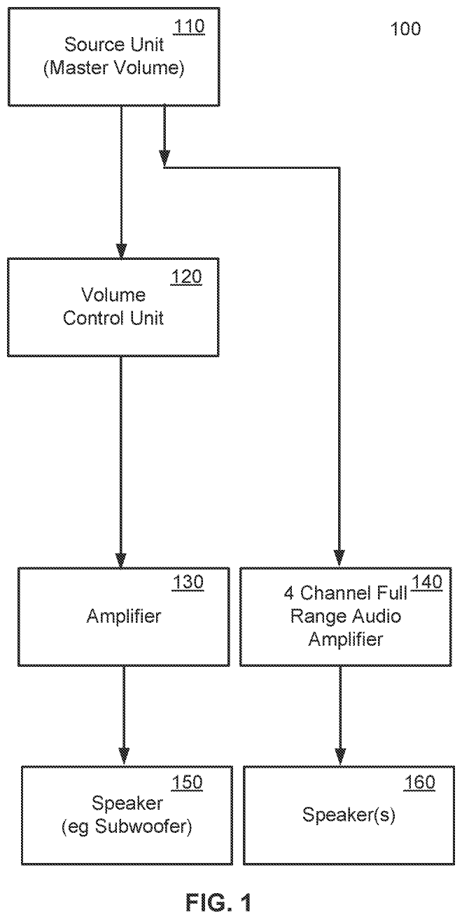

With reference now to FIG. 1, a volume control system 100 is illustrated. The volume control system 100 may comprise a source unit 110, and a volume control unit 120 (or sub-frequency volume control unit). In an example embodiment, the volume control system further comprises an amplifier 130 (or sub-frequency amplifier). The volume control system may optionally include a full range audio amplifier 140. The volume control system 100 may further comprise a subwoofer 150. The volume control system 100 may further comprise speakers 160.

In accordance with various example embodiments, the volume control system 100 may be installed for use in a noisy environment. For example, the volume control system 100 may be implemented to enhance audio perception in a vehicle. In various example embodiments, the vehicle may be a recreational vehicle, a four-wheeler, a three-wheeler, a motorcycle, a ski-doo, a jet-ski, a motorboat, a truck or car, and/or the like. In these vehicles, there is often significant changes in the noise due to motor, wind, road noise, and the like as the users drive these vehicles over differing terrain, at different speeds, in various kinds of weather and the like.

The volume control system 100 may be installed or located in a vehicle having a source unit 110. The source unit 110 may be, for example, an audio device such as a stereo, a radio, a car receiver, a deck, an in-dash stereo, and/or the like. The source unit may also be connected via cable or Bluetooth to various sources of media, such as smartphones, MP3 players and the like. Moreover, the source unit 110 may be any component that outputs an audio signal for amplification by amplifiers prior to the audio signal being provided to speakers for listening to the audio signal.

In particular, the source unit 110 may comprise a master volume controller. The master volume controller may be any device configured to variably adjust the volume of an audio signal output from the source unit 110. The master volume controller may comprise, for example, a knob, a slider, a dial, an electronic input and/or the like that is configured to set the master volume. Moreover, in another example embodiment, source unit 110 may receive input from an external source (e.g. via Bluetooth from a smartphone) that controls the master volume. In accordance with an example embodiment, the master volume controller may be configured to provide an output audio signal with a volume level between a 0% volume level and a 100% volume level. The 100% volume level may, in various example embodiments, be a maximum permissible volume level. For example, the 100% volume level may be set to protect the subwoofer 150 from damage due to exceeding its limits.

In an example embodiment, the source unit 110 is configured to generate a first audio signal and a second audio signal. In another example embodiment, not shown, the source unit 110 is configured to generate a source unit audio signal that, after being output from the source unit, is split into the first audio signal and the second audio signal. The source unit may be configured to provide the second audio signal to a speaker 160. In another example embodiment, the second signal is provided to a full range audio amplifier 140. The full range amplifier may be configured to amplify the second audio signal and provide it to speaker(s) 160. In this regard, the volume of the music played on the speakers 160 is only controlled by the master volume controller at the source unit 110. In accordance with various example embodiments, the speaker 160 may be called a mid-bass speaker, a tweeter, a mid-range speaker, and or the like.

In a further example embodiment, the source unit 110 is configured to provide the first audio signal to the volume control unit 120 (which in some embodiments may comprise a sub-frequency volume control unit). The source unit 110 does not provide the audio signal directly to the amplifier 130. Stated another way, the source unit 110 only provides the audio signal to the amplifier 130 via the volume control unit 120. Although described herein as a volume control unit 120 configured to operate as described herein at any suitable frequency, in a specific example embodiment, the volume control unit 120 is a sub-frequency volume control unit.

The amplifier 130 is configured to receive the audio signal from the volume control unit 120, to further amplify the received signal and to provide the amplified signal (e.g., a sub-amplifier output signal) to the subwoofer 150. In an example embodiment the amplifier may configured to operate at any suitable frequency. In accordance with various example embodiments, the amplifier 130 may be called a sub-amplifier, a driver or sub-driver. In an example embodiment, the sub-amplifier is any amplifier suitable for amplifying sub-frequencies.

In an example embodiment, the speaker 150 is any suitable speaker. In one specific embodiment, the speaker 150 is a subwoofer is configured to receive the amplified signal from the sub-amplifier and to play those sub-frequencies on speakers designed specifically for that sub-frequency range.

In an example embodiment, the volume control unit 120 is configured to receive the first audio signal, to amplify the audio signal if, and only if, the master volume controller is providing the first audio signal at less than the 100% volume level, and to output an amplified signal based on user input to the volume control circuit.

In an example embodiment, the volume control unit 120 further comprises a volume control input device. In an example embodiment, the volume control unit 120 further comprises a variable volume control input device. In an example embodiment, the volume control input device is a knob. However, the volume control input device may comprise a knob, a slider, a dial, an electronic input and/or any device suitable for adjusting the amplification of the first signal. In an example embodiment, the volume control unit 120 is configured to provide the amplified first signal, to the amplifier 130 at an amplification level that is manually adjustable to be different from the second audio signal (that is provided for example, to the full range audio amplifier or the speaker 160). In an example embodiment, the volume control unit 120 limits amplification based on a set voltage threshold selected to protect the speaker 150 (e.g., prevent damaging the subwoofer).

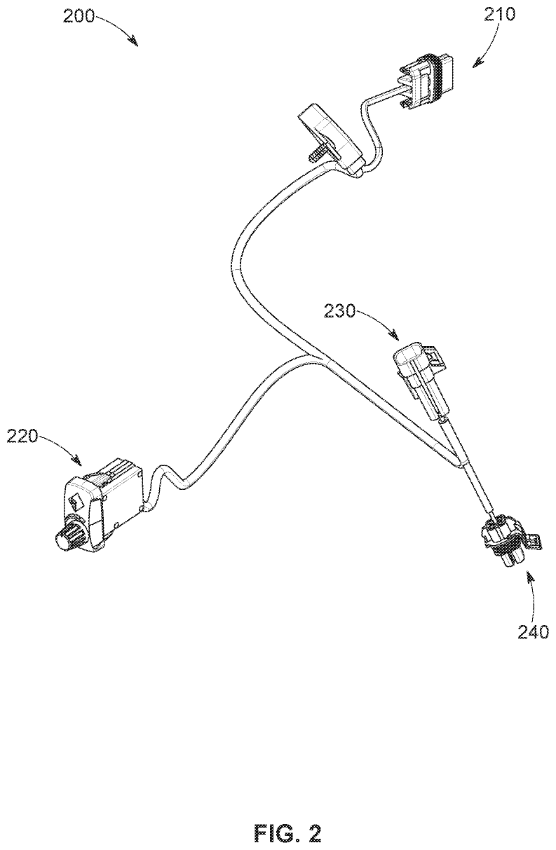

With reference now to FIG. 2, in an example embodiment, a portion of a volume control system 200 is illustrated. In this example embodiment, the portion of the volume control system 200 comprises a power connector 210, a sub-frequency volume control unit 220), a sub-amplifier connector 230, and a source unit connector 240. The power connector 210 may be configured to be electrically connected to a power source, such as a battery (not shown). The power connector 210 may be configured to provide power from the power source to the sub-frequency volume control unit 220, to the sub-amplifier (not shown in FIG. 2) via the sub-amplifier connector 230, and to the source unit (not shown in FIG. 2) via the source unit connector 240).

In an example embodiment, the source unit connector 240 is configured to receive the first audio signal from the source unit, and to provide the first audio signal to the sub-frequency volume control unit 220. As described above, the sub-frequency volume control unit 220 is configured to receive the first audio signal from the source unit via the source unit connector 240, to selectively boost the sub-frequencies, and to provide the further amplified (boosted) sub-frequency signal to the sub-amplifier via the sub-amplifier connector 230. Lastly, the sub-amplifier connector 230 is configured to receive the further amplified sub-frequency signal from the sub-frequency volume control unit 220 and provide it to the sub-amplifier. Although FIG. 2 has been described in the context of sub-frequency volume control, the same structure may be used for differentiating volume control at any frequency.

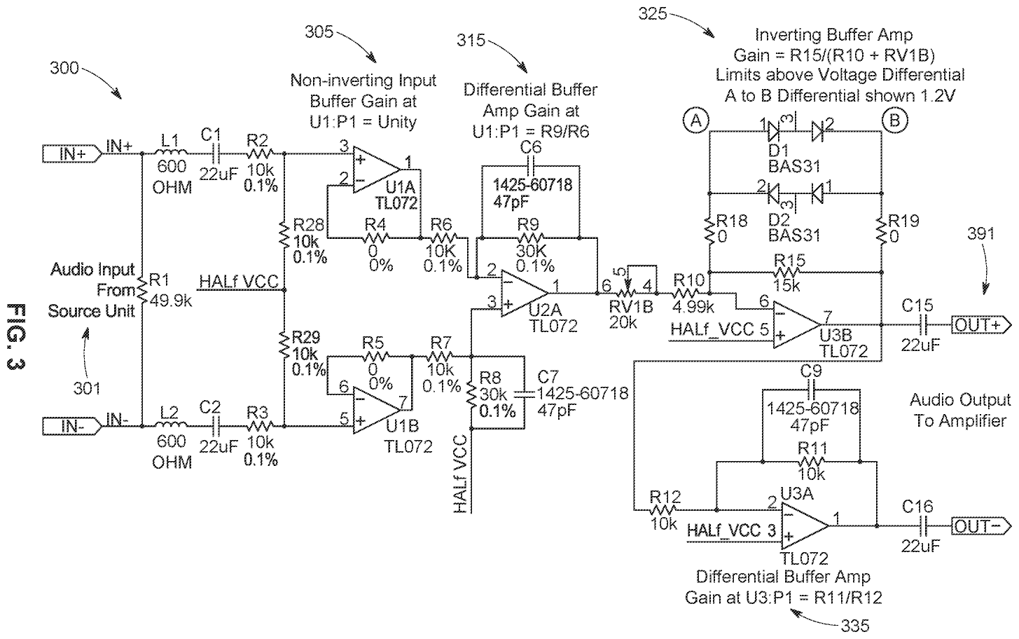

With reference now to FIG. 3, in an example embodiment, the volume control unit 120 comprises a volume control circuit 300. The volume control circuit 300 may comprise an audio input 301 for receiving a first audio signal from the source unit. The circuit 300 may further comprise a non-inverting input buffer 305 for receiving the first audio signal from the audio input 301, buffering the first audio signal, and providing the buffered first audio signal to a differential buffer amplifier 315. The non-inverting input buffer 305, in an example embodiment has a unity gain. The differential buffer amplifier may be configured to convert differential signaling to non-differential signaling.

In an example embodiment, the differential buffer amplifier 315 is configured to receive the buffered first audio signal, to amplify the buffered first audio signal, and to provide the amplified buffered first audio signal to an inverting buffer amplifier 325. In an example embodiment, the differential buffer amplifier illustrated has a gain of 3/1, though other gain ratios may be used.

In an example embodiment, the inverting buffer amplifier 325 is configured to receive the amplified/buffered first audio signal, amplify this signal, but limit the amplification to a predetermined threshold voltage level. In the illustrated embodiment, the amplification has a gain of 5/3, though other gain ratios may be used. The inverting buffer amplifier 325 may further comprise Zener diodes configured to limit the voltage differential A to B to 1.2V, though other voltage limits may be used. The voltage limit threshold may be set through the selection of the Zener diodes. In one example embodiment, the voltage limit threshold is determined when the components of the inverting buffer amplifier 325 are selected. In another example embodiment, the voltage limit threshold may be adjusted through use of adjustable components. Although Zener diodes are used in this example embodiment, other components may be used for providing a voltage limit threshold. The inverting buffer amplifier 325 may provide an output signal from the volume control circuit 300, providing a selectable variable amplification of the input first audio signal to the amplifier 130. Another differential buffer amplifier 335 may be configured to convert non-differential signaling back to differential signaling. The differential buffer amplifier 335 illustrated may have a gain of 1. Thus, the sub-frequency volume control circuit 300, may comprise an audio signal output 391 configured to output the manually selectable additional amplified first audio signal.

Thus, in this example embodiment, the volume control circuit 300 comprises a boost circuit configured to pass the first audio signal on to the amplifier, without amplification, if the master volume level is at 100%, and configured to boost the volume somewhere between the master volume level and 100% volume when the master volume is less than 100%. Although various example values for the resistors, capacitors, inductors and the like or provided in FIG. 3, it should be understood that any suitable values may be used to boost the volume to be between the master volume level and 100% volume when the master volume is less than 100%. Moreover, other suitable circuit architectures may be used to provide this safe audio boost control.

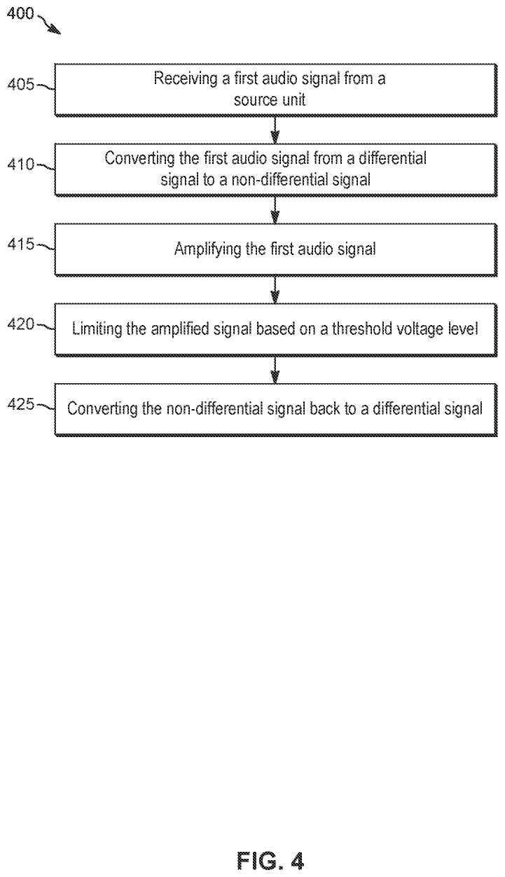

With reference now to FIG. 4, in accordance with an example embodiment, a method of safely providing additional variable gain to sub-frequency audio signals to a subwoofer is provided. In an example embodiment, the method 400 comprises the steps of receiving (405) a first audio signal from a source unit 110. The method 400 may further comprise converting (410) the first audio signal from a differential signal to a non-differential signal. The method 400 may further comprise amplifying (415) the first audio signal. The method 400 may further comprise limiting (420) the amplified signal based on a threshold voltage level. The method 400 may further comprise converting (425) the non-differential signal back to a differential signal.

In a sub-frequency example embodiment, the method (400) may further comprise controlling a volume output by a subwoofer by providing the output of the sub-frequency volume control circuit to the sub-amplifier. In this example embodiment, the method 400 further comprises providing the audio signal without amplification as the sub-amplifier input signal if the source unit is providing the source unit signal at the 100% volume level. In this example embodiment, the method 400 further comprises generating the sub-amplifier input signal by amplifying the audio signal sufficient to cause the volume output by the subwoofer to be between the master volume and 100% master volume when the master volume is less than 100%.

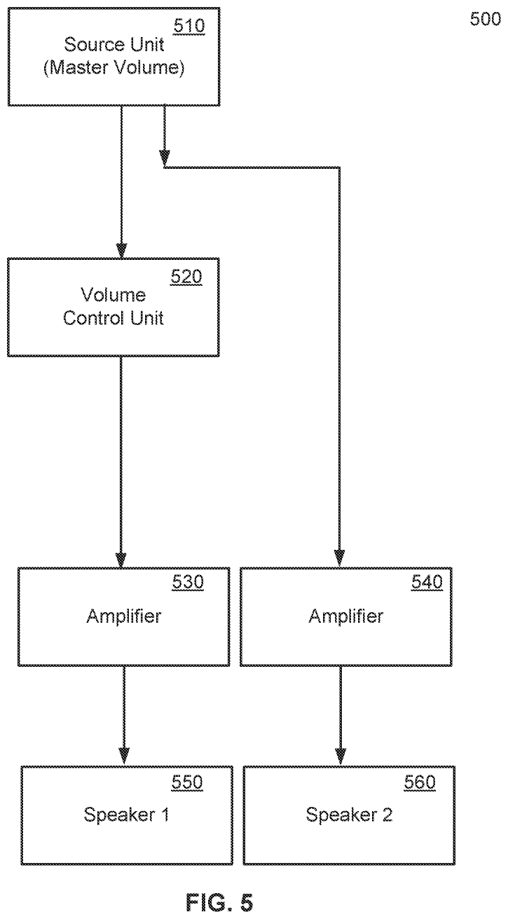

With reference now to FIG. 5, an example volume control system 500 may comprise a source unit 510, a volume control circuit 520, a first speaker 550 and a second speaker 560. The source unit 510 may be configured to provide a first audio signal and a second audio signal. The first audio signal and the second audio signal may be the same audio signal output from a single output and then split outside of the source unit 510 as shown in FIG. 5. In another example embodiment, the first and second signal are separately output from the source unit 510 (e.g., through a first output and a second output of the source unit). In either event, the source unit may comprise a master volume controller for providing the first audio signal and the second audio signal with a volume level between a 0% volume level and a 100% volume level, wherein the volume level of the two signals are the same and/or are adjusted together with the same master volume controller (as opposed to two signals that are each controlled with their own volume controller).

In an example embodiment, the volume control circuit 520 is configured to receive the first audio signal, and to amplify the first audio signal, in accordance with user input to the volume control circuit 520 for outputting a first amplified signal, if, and only if, the master volume controller is providing the first audio signal at less than the 100% volume level. A volume control circuit only amplifies the first audio signal and not the second audio signal in this embodiment. In another (not shown), each signal path may comprise its own volume control circuit. The volume control circuit 520 may be similar to the volume control circuits described in connection with FIG. 1 (120), FIG. 2 (220), and FIG. 3 (300), for example. In an example embodiment the volume control circuit 520, 300/volume control unit 120, 220, comprises a variable volume control input device. The device may provide an analog input for the degree of amplification to provide to the first signal (limited by the threshold limiter to protect the first speaker). In an example embodiment, the volume control unit 120, 220/volume control circuit 300, 520, is configured to provide the first amplified signal, at an amplification level that is manually adjustable to be different from the second audio signal. In an example embodiment, the volume control unit 120, 220/circuit 300, 520, is a boost circuit.

In an example embodiment, the volume control system 500 is configured to pass the first amplified signal to the first speaker 550, and to pass the second audio signal to the second speaker 560. In accordance with yet further example embodiments, the volume control system 500 may comprise a first amplifier 530 for receiving the first amplified signal and for further amplifying the first amplified signal and providing the further amplified signal to the first speaker 550. In some example embodiments, this first amplifier 530 is a sub-amplifier and the first speaker is a subwoofer. In yet another example embodiment, the volume control system 500 may comprise a second amplifier 540 for receiving the second signal and for amplifying the second signal and providing the amplified second signal to the second speaker 560.

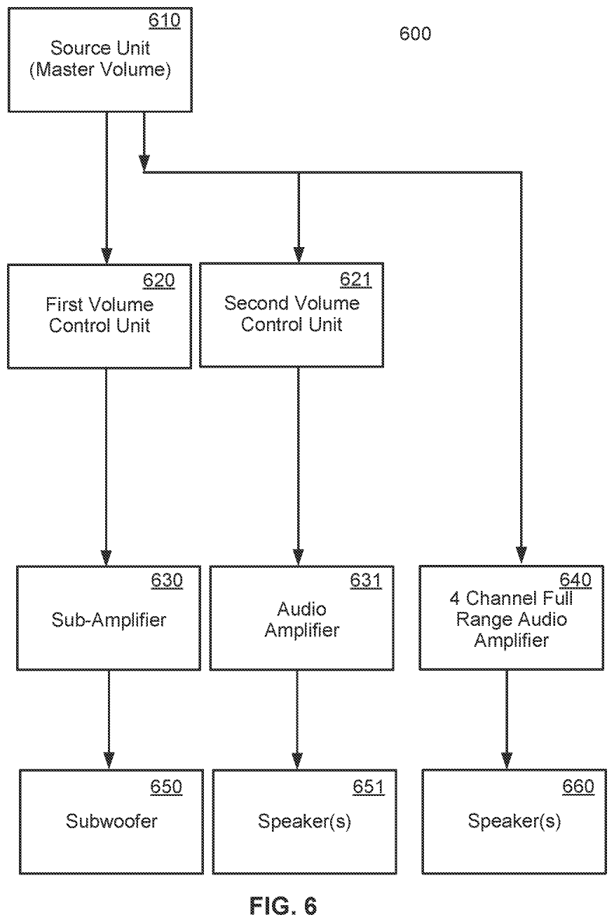

With reference now to FIG. 6, a volume control system 600 may comprise a source unit 610, a first volume control circuit 620, a second volume control circuit 621, a first speaker 650, a second speaker 651, and a third speaker 660. The source unit 610 may be configured to provide a first audio signal and a second audio signal, similar to the source unit 510 (e.g., through a first output and a second output of the source unit). The source unit 610 may further provide a third audio signal, either through a third output, or split from the second audio signal. In either event, the source unit 610 may comprise a master volume controller for providing the first audio signal, the second audio signal, and the third audio signal, all with a volume level between a 0% volume level and a 100% volume level, wherein the volume level of the three signals are the same and/or are adjusted together with the same master volume controller (as opposed to three signals that are each controlled with their own volume controller).

In an example embodiment, the first volume control circuit 620 and the second volume control circuit 621 are respectively configured to receive the first and second audio signals, and to respectively amplify the first and second audio signals, in accordance with user input to the volume control circuits 620/621 for outputting respective first and second amplified signals, if, and only if, for each the master volume controller is providing the respective audio signal at less than the 100% volume level. A volume control circuit only amplifies the first and/or second audio signal and not the third audio signal in this embodiment. In another (not shown), each signal path may comprise its own volume control circuit. The volume control circuits 620/621 may be similar to the volume control circuits described in connection with FIG. 1 (120), FIG. 2 (220), and FIG. 3 (300), FIG. 5 (520) for example.

In an example embodiment, the volume control system 600 is configured to pass the first amplified signal to the first speaker 650, to pass the second audio signal to the second speaker 651, and to pass the third signal to the third speaker 660. In accordance with yet further example embodiments, the volume control system 600 may comprise a first amplifier 630 for receiving the first amplified signal and for further amplifying the first amplified signal and providing the further amplified signal to the first speaker 650. In some example embodiments, this first amplifier 630 is a sub-amplifier and the first speaker 650 is a subwoofer. In accordance with yet further example embodiments, the volume control system 600 may comprise a second amplifier 631 for receiving the second amplified signal and for further amplifying the second amplified signal and providing the second further amplified signal to the second speaker 651. In some example embodiments, this second amplifier 631 is an audio amplifier. In an example embodiment, volume control system 600 may comprise a third amplifier 640 for receiving the third signal and for amplifying the third signal and providing the amplified third signal to the third speaker 660.

Thus, in an example embodiment the volume control unit facilitates multizone audio enhancement from a single source (and a single master volume control) so that differential volumes can be provided from speakers associated with first and second audio signals respectively. Moreover the volume control unit may be used on a single channel, on dual channels (with a volume control unit associate with each channel), or any suitable number of channels. In one example, a boat may have speakers playing music to both the occupants of the boat and to the person wake-boarding behind the boat, and it may be desirable to boost the volume to the speakers on the wake tower, but not inside the boat (at least while moving fast). The boost knob for the volume control unit can facilitate selectively boosting the channel to the speakers on the wake tower, without fear of damaging the wake tower speakers. In another example embodiment, an all-terrain vehicle may be improved by providing a bass boost knob for turning up the volume to the subwoofer when the vehicle is driving and there is a high level of engine, wind, and road noise, again without fear of damaging the subwoofer. The volume control unit can provide audio enhancement in numerous other applications where adding one or more such units can provide the ability to audio boost the channel with which it is in line.

Example embodiments of the systems, methods, and devices described herein may be implemented in hardware, software, firmware, or some combination of hardware, software, and firmware. For example, the block and schematic diagrams of FIGS. 1-3 may be implemented in hardware, software, firmware, or some combination of hardware, software, and firmware.

In the present disclosure, the following terminology will be used: The singular forms “a.” “an,” and “the” include plural referents unless the context clearly dictates otherwise. Thus, for example, reference to an item includes reference to one or more items. The term “ones” refers to one, two, or more, and generally applies to the selection of some or all of a quantity. The term “plurality” refers to two or more of an item. The term “about” means quantities, dimensions, sizes, formulations, parameters, shapes, and other characteristics need not be exact, but may be approximated and/or larger or smaller, as desired, reflecting acceptable tolerances, conversion factors, rounding off, measurement error and the like and other factors known to those of skill in the art. The term “substantially” means that the recited characteristic, parameter, or value need not be achieved exactly, but that deviations or variations, including, for example, tolerances, measurement error, measurement accuracy limitations and other factors known to those of skill in the art, may occur in amounts that do not preclude the effect the characteristic was intended to provide. Numerical data may be expressed or presented herein in a range format. It is to be understood that such a range format is used merely for convenience and brevity and thus should be interpreted flexibly to include not only the numerical values explicitly recited as the limits of the range, but also interpreted to include all of the individual numerical values or sub-ranges encompassed within that range as if each numerical value and sub-range is explicitly recited. As an illustration, a numerical range of “about 1 to 5” should be interpreted to include not only the explicitly recited values of about 1 to about 5, but also include individual values and sub-ranges within the indicated range. Thus, included in the numerical range are individual values such as 2, 3 and 4 and sub-ranges such as 1-3, 2-4 and 3-5, etc. The same principle applies to ranges reciting only one numerical value (e.g., “greater than about 1”) and should apply regardless of the breadth of the range or the characteristics being described. A plurality of items may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary. Furthermore, where the terms “and” and “or” are used in conjunction with a list of items, they are to be interpreted broadly, in that any one or more of the listed items may be used alone or in combination with other listed items. The term “alternatively” refers to selection of one of two or more alternatives, and is not intended to limit the selection to only those listed alternatives or to only one of the listed alternatives at a time, unless the context clearly indicates otherwise.

It should be appreciated that the particular implementations shown and described herein are illustrative of the example embodiments and their best mode and are not intended to otherwise limit the scope of the present disclosure in any way. Furthermore, the connecting lines shown in the various figures contained herein are intended to represent exemplary functional relationships and/or physical couplings between the various elements. It should be noted that many alternative or additional functional relationships or physical connections may be present in a practical device.

As one skilled in the art will appreciate, the mechanism of the present disclosure may be suitably configured in any of several ways. It should be understood that the mechanism described herein with reference to the figures is but one exemplary embodiment of the disclosure and is not intended to limit the scope of the disclosure as described above.

It should be understood, however, that the detailed description and specific examples, while indicating exemplary embodiments of the present disclosure, are given for purposes of illustration only and not of limitation. Many changes and modifications within the scope of the instant disclosure may be made without departing from the spirit thereof, and the disclosure includes all such modifications. The corresponding structures, materials, acts, and equivalents of all elements in the claims below are intended to include any structure, material, or acts for performing the functions in combination with other claimed elements as specifically claimed. The scope of the disclosure should be determined by the appended claims and their legal equivalents, rather than by the examples given above. For example, the operations recited in any method claims may be executed in any order and are not limited to the order presented in the claims. Moreover, no element is essential to the practice of the disclosure unless specifically described herein as “critical” or “essential.”

What is claimed:

1. A volume control system, comprising:
a source unit providing a first audio signal and a second audio signal, wherein the source unit has a master volume controller for providing the first audio signal and the second audio signal with a volume level between a 0% volume level and a 100% volume level;
a volume control circuit configured to receive the first audio signal, to amplify the first audio signal, in accordance with user input to the volume control circuit for outputting a first amplified signal, if, and only if, the master volume controller is providing the first audio signal at less than the 100% volume level;
a first speaker; and
a second speaker, wherein the first amplified signal is provided to the first speaker, and wherein the second audio signal is provided to the second speaker.

2. The volume control system of claim 1, wherein the volume control circuit further comprises a volume control input device for providing the user input.

3. The volume control system of claim 1, wherein the volume control circuit further comprises a variable volume control input device for providing the user input.

4. The volume control system of claim 2, wherein the volume control input device is a knob for providing the user input.

5. The volume control system of claim 1, wherein the volume control circuit is configured to provide the first amplified signal, at an amplification level that is manually adjustable to be different from the second audio signal.

6. The volume control system of claim 1, wherein the volume control circuit limits amplification of the first audio signal based on a set voltage threshold selected to protect the first speaker.

7. The volume control system of claim 1, wherein the volume control circuit is a sub-frequency volume control circuit, wherein the first audio signal is a sub-frequency signal and is provided from a first output of the source unit, wherein the first speaker is a subwoofer, and wherein the second audio signal is provided from a second output of the source unit, the volume control system further comprising:
a sub-amplifier for receiving the first amplified signal, further amplifying the first amplified signal and providing a sub-amplifier output signal to the subwoofer.

8. The volume control system of claim 7, further comprising a full-range audio amplifier to receive the second audio signal from the source unit, and to provide the further amplified second audio signal to the second speaker.

9. The volume control system of claim 7, wherein the sub-frequency volume control circuit is a boost circuit, wherein the boost circuit is configured to pass the first audio signal on to the sub-amplifier, without amplification, if the master volume level is at 100%, and wherein the boost circuit is configured to boost the volume to a controllable level between the master volume level and 100% volume when the volume level set by the master volume controller is less than 100%.

10. The volume control system of claim 9, wherein the boost circuit comprises an inverting buffer amplifier and wherein the inverting buffer amplifier is configured to limit the amplification above a predetermined threshold voltage level.

11. The volume control system of claim 1, further comprising a second volume control circuit for receiving the second audio signal, to pass the second audio signal through, without amplification, if the master volume level is at 100%, and to boost the volume to a desired level between the master volume level and 100% volume when volume level set by the master volume controller is less than 100% to provide a second amplified signal.

12. The volume control system of claim 11, wherein the second amplified signal is provided to the second speaker, and wherein the second audio signal is further provided to a third speaker either (1) directly, or (2) via a full range audio amplifier.

13. A volume control unit for providing additional control of volume in a first audio signal provided from a source unit to a first speaker, without exceeding a maximum volume level of the first speaker, the source unit having a master volume controller and a maximum volume level, the master volume controller controlling the volume of the first audio signal and a second audio signal, the volume control unit comprising:
a circuit input for receiving the first audio signal from the source unit;
a volume control circuit for receiving the first audio signal and for generating a first amplified signal for the first speaker;
a variable volume control input device, wherein the first amplified signal is amplified by an amount that is variably selected manually using the variable volume control input device, and wherein the volume control circuit is configured to amplify the first audio signal if, and only if, the master volume controller is providing the first audio signal at less than the maximum volume level; and
a circuit output for providing the first amplified signal to the first speaker.

14. The volume control unit of claim 13, wherein the variable volume control input device is a knob.

15. The volume control unit of claim 13, wherein the volume control circuit is configured to provide the first amplified signal at an amplification level that is manually adjustable to be different from the second audio signal.

16. The volume control unit of claim 13, wherein the volume control circuit is a sub-frequency volume control circuit, wherein the first audio signal is a sub-frequency signal and is provided from a first output of the source unit, wherein the first speaker is a subwoofer, and wherein the second audio signal is provided from a second output of the source unit, a volume control system further comprising:
a sub-amplifier for receiving the first amplified signal, further amplifying the first amplified signal and providing a sub-amplifier output signal to the subwoofer, wherein the sub-frequency volume control circuit limits amplification based on a set voltage threshold selected to protect the subwoofer.

17. The volume control unit of claim 15, wherein the volume control circuit comprises an inverting buffer amplifier and wherein the inverting buffer amplifier is configured to limit the amplification above a predetermined threshold voltage level.

18. A method of controlling an output volume level of a speaker, beyond volume control from a master volume controller of a first audio signal from a source unit, wherein the master volume controller controls the volume level (a master volume) of the first audio signal and a second audio signal, the method comprising:
receiving the first audio signal from the source unit at a volume control circuit, the first audio signal having a power level based on the master volume controller associated with the source unit;
controlling a volume output by the speaker by generating a volume control output signal that is based on the first audio signal from the source unit, wherein:
the volume control output signal comprises the first audio signal without amplification, if the source unit is providing the first audio signal at the 100% volume level; and
the volume control output signal comprises an amplified first audio signal in accordance with user input to the volume control circuit, wherein the amplified first audio signal is amplified sufficient to cause the volume output by the speaker to be between the master volume and 100% master volume when the master volume is less than 100%.

19. The method of claim 18, further comprising at least one of:
converting the first audio signal from a differential signal to a non-differential signal before manual selection of amplification of the first audio signal;
selectively boosting sub-frequency portions of an audio output from the source unit; and
selectively boosting sub-frequency portions of the audio output from the source unit without changing the full range audio volume levels.
